(19) United States
(12) Patent Application Publication
(10) Pub. No.: US 2015/0041102 A1
(43) Pub. Date: Feb. 12, 2015

(54) Radiator Clip Structure and A Tool for the Structure

(71) Applicant: Qingdao Mefine Electronics Co., Ltd, Qingdao (CN)

(72) Inventors: Yongshan Li, Jimo (CN); Hankui Liu, Harbin (CN); Renjie Zhang, Jimo (CN); Pengliang Lv, Qingdao (CN)

(73) Assignee: QINGDAO MEFINE ELECTRONICS CO., LTD, Qingdao (CN)

(21) Appl. No.: 13/961,667

(22) Filed: Aug. 7, 2013

(51) Int. Cl. H05K 7/20; B23P 15/26

(52) U.S. Cl. CPC H05K 7/20418; B23P 15/26
USPC 165/76; 29/726

(57) ABSTRACT

A radiator clip structure and comprising skewed slots on the back of the radiator, locking slots for receiving a tool for mounting and dismounting the structure above the skewed slots and a main part of the radiator clip further comprising a u-shaped panel with a long edge and a short edge, and a notch between the long edge of the main part of the radiator clip and the bottom edge of the u-shaped panel. A tool used for mounting and dismounting the radiator clip for the above mentioned structure, comprising a pressing block with a concave surface, a convex spot, a handle, and a concave part on the end of the said handle.

### FIELD OF INVENTION

The present invention relates to a radiator structure for electronic products, specifically, a radiator clip structure and a tool to be used for this structure for mounting and dismounting the structure.

### BACKGROUND

As electronic technology develops constantly, power devices such as large-power IGBT, field-effect tubes, thyristors, bipolar transistors, etc. have become increasingly mature. Based on these devices, electronic products such as electronic ballasts, switching power supply, amplifiers, controllers for electric vehicles, are widely used. For these products, bolts or traditional U-shaped spring clips are used to fasten the power devices and their radiators.

When bolts are used, there must be corresponding holes on the radiators and the power devices so that the bolts can connect the two through these holes; the tolerance of the positions of these holes is very demanding, resulting in an increase in the complexity of the manufacturing process of the radiators and welding of power devices, higher cost, lower subsequent installation efficiency and higher labor cost.

As for the conventional U-shaped spring clips, they can easily slip off. Therefore, additional process such as gluing is necessary. Additionally, the size of radiators will be limited, not to exceed the power devices in height. For enclosure cooling, the outward appearance will be affected.

As discussed above, the conventional mounting methods of the radiator reveal very obvious shortcomings, including:

complicated manufacturing processes, which may require drilling and other works; low installation efficiency; consistency of installation hard to control; unsatisfactory outward appearance.

### SUMMARY OF INVENTION

This invention patent is aimed at providing a radiator clip structure featuring simplicity in structure, convenient manufacturing, efficient installation, consistency, and reliability along with a tool to be used for this structure mounting and dismounting the structure.

To achieve the above features, the fastening radiator clip structure of this invention patent can comprise skewed slots on the back of the radiator, locking slots for the dismounting tool above the skewed slots and a main part of the radiator clip. The main part of the radiator clip is a U-shaped panel with long and short edges. On the long edge, there is a concave surface, while the short edge can be locked inside the skewed slots. The concave surface on the long edge of the main part of the radiator clip can be placed onto a power device on the back of the radiator. Between the long edge of the main part of the radiator clip and the bottom edge of the U-shaped panel, there is a notch.

A tool used for the above mentioned structure for mounting and dismounting purpose can comprise a pressing block with a concave surface. In the front of the pressing block there is a convex spot which can be put into the locking slots. Above the pressing block, there is a handle, on the end of which there is a concave part able to be put into the notch for disassembly of the main part of the radiator clip.

The advantages of this invention patent include: Due to the skewed slots on the back of the radiator as well as the main part of the radiator clip, the power device can be securely fastened with the radiator. The tool specifically designed for mounting and dismounting of the radiator clip makes it convenient to dismount the main part of the radiator clip and therefore enables efficient installation, reliable fastening between the power devices and the radiators, and consistency in installation. Moreover, this invention doesn't require drilling on the radiators or reshaping of the power devices, and reduces unsatisfactory influences traditional methods have on the products' outward appearance. It features simple structure, convenient manufacturing, efficient installation, consistency and reliable fastening.

### BRIEF DESCRIPTION OF THE DRAWINGS

Further features and advantages of the present device, as well as the structure and operation of various embodiments of the present device, will become apparent and more readily appreciated from the following description of the preferred embodiments, taken in conjunction with the accompanying drawings of which:

FIG. 1 is a section view of the radiator for which this invention patent of radiator clip structure is designed.

FIG. 2 is a three-dimensional structure diagram of the main part of the radiator clip.

FIG. 3 is a structure diagram of the specially designed tool for mounting and dismounting the structure.

FIG. 4 is a diagram illustrating the mounting of the radiator clip structure.

FIG. 5 is a diagram illustrating the dismounting of the radiator clip structure.

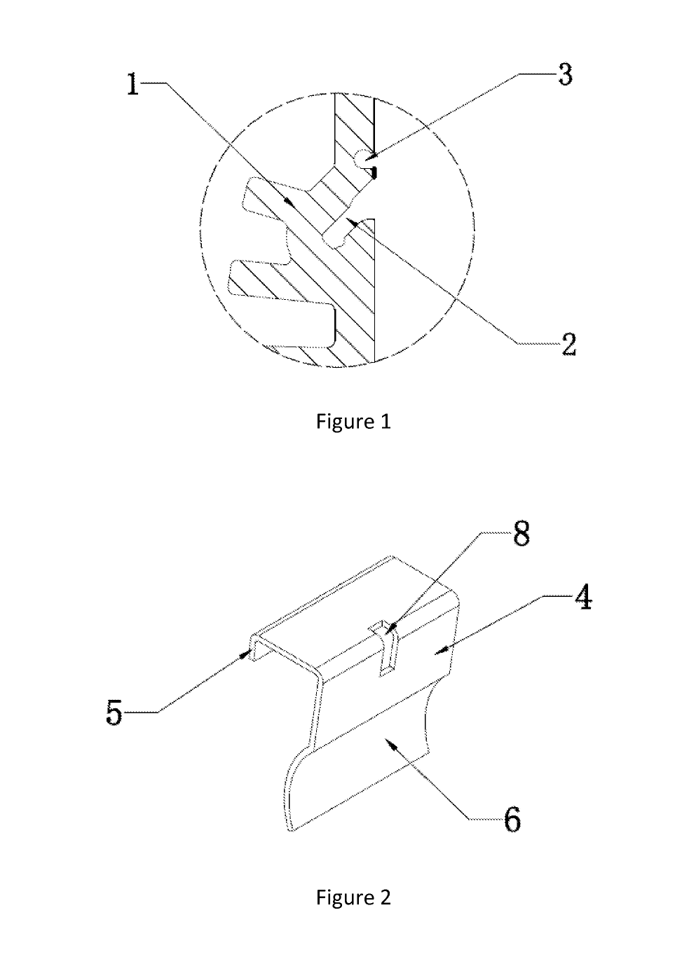

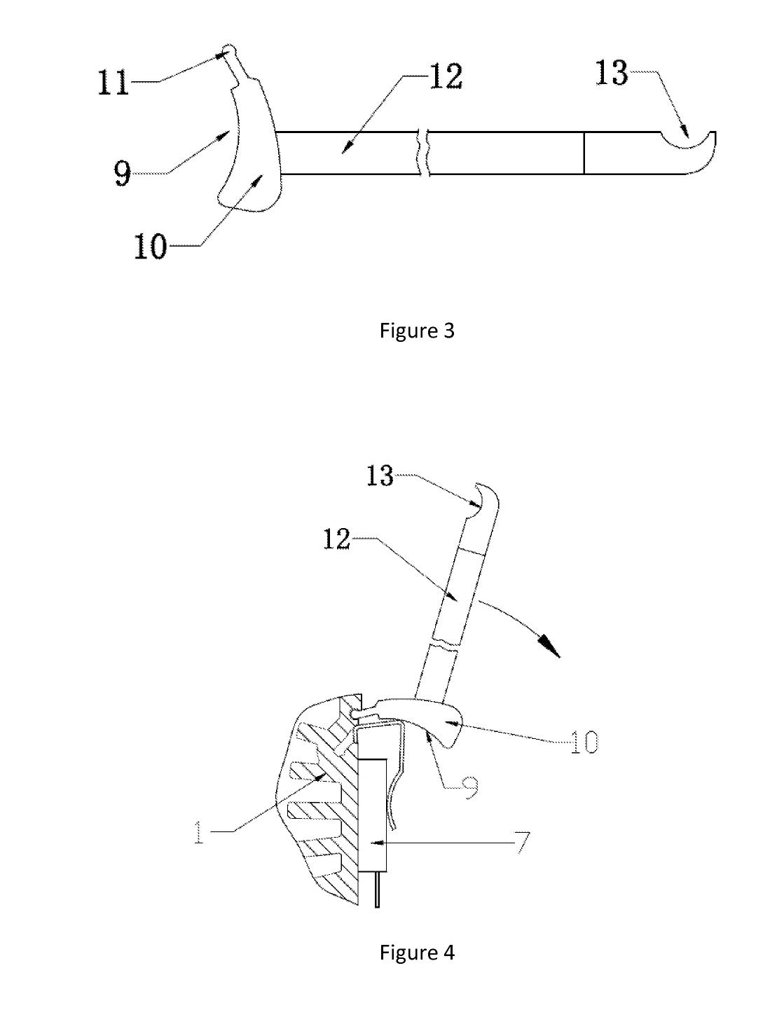

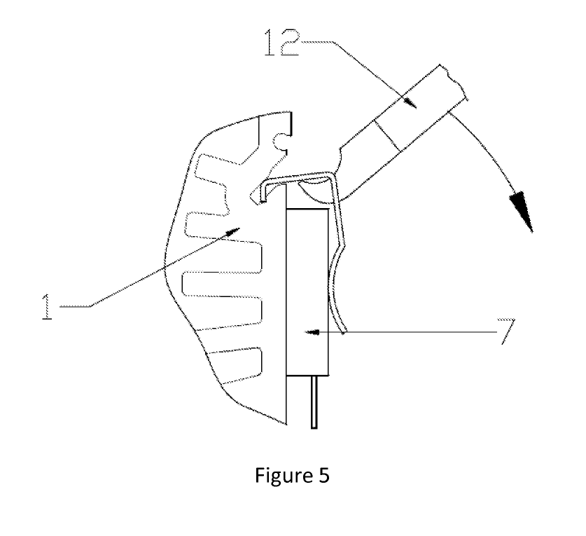

### DETAILED DESCRIPTION

In the following detailed description, reference is made to the accompanying drawings that form a part hereof, and in which is shown by way of illustration specific implementations that may be practiced. These implementations are described in sufficient detail to enable those skilled in the art to practice the implementations, and it is to be understood that other implementations may be utilized and that logical, mechanical, electrical and other changes may be made without departing from the scope of the implementation. The following detailed description is, therefore, not to be taken in a limiting sense.

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Based on the pictures and the detailed mode of execution, here is the further detailed description of this invention patent of radiator clip structure and dismounting tool for it.

As shown in the picture, the fastening radiator clip structure of this invention patent can comprise skewed slots 2 on the back of the radiator 1, locking slots 3 to receive a tool for mounting and dismounting purpose above the skewed slots 2 and a main part of the radiator clip. The main part of the radiator clip can comprise U-shaped panel with long 4 and short 5 edges. On the long edge 4, there can be a concave surface 6, while the short edge 5 can be locked inside the skewed slots 2 on the radiator clip structure. The concave surface 6 on the long edge 4 of the main part of the radiator clip can be placed onto a power device 7 on the back of the radiator 1 to lock it in place. Between the long edge 4 of the main part of the radiator and the bottom edge of the U-shaped panel, there is a notch 8.

A tool used for the above mentioned structure can comprise a pressing block 10 with a concave surface 9. In the front of the pressing block 10 there is a convex spot 11 which can be put into the locking slots 3. Above the pressing block 10, there is a handle 12, on the end of which there is a concave part 13 able to be put into the notch 8 for disassembly of the main part of the radiator clip.

What is claimed is:

1. A radiator clip structure, comprising:
skewed slots on the back of the radiator,
locking slots for above the skewed slots, and
a main part of the radiator clip;
wherein the main part of the radiator clip is a U-shaped panel with a long edge and a short edge; wherein the long edge further comprise a concave surface; wherein the short edge can be locked inside the said skewed slots; wherein the concave surface on the long edge of the main part of the radiator clip can be placed onto a power device to lock the radiator into the power device; wherein between the long edge of the main part of the radiator and the bottom edge of the U-shaped panel, there is a notch.

2. A tool used for mounting and dismounting the radiator clip structure comprising:
a pressing block with a concave surface,
a convex spot,
a handle, and
a concave part on the end of the said handle.
